(19) United States
(12) Patent Application Publication
(10) Pub. No.: US 2019/0198655 A1
(43) Pub. Date: Jun. 27, 2019

(54) SEMICONDUCTOR DEVICE

(71) Applicants: Kabushiki Kaisha Toshiba, Minato-ku (JP); Toshiba Infrastructure Systems & Solutions Corporation, Kawasaki-shi (JP)

(72) Inventor: Keiichi MATSUSHITA, Ota (JP)

(73) Assignees: Kabushiki Kaisha Toshiba, Minato-ku (JP); Toshiba Infrastructure Systems & Solutions Corporation, Kawasaki-shi (JP)

(21) Appl. No.: 16/021,984

(22) Filed: Jun. 28, 2018

(30) Foreign Application Priority Data
Dec. 26, 2017 (JP) 2017-249374

(51) Int. Cl. H01L 29/778; H01L 29/20; H01L 29/205; H01L 29/417; H01L 23/31; H01L 21/02; H01L 21/306; H01L 21/24; H01L 29/66

(52) U.S. Cl. CPC H01L 29/7787; H01L 29/2003; H01L 29/205; H01L 29/41766; H01L 23/3171; H01L 29/66462; H01L 21/0262; H01L 21/30621; H01L 21/246; H01L 21/0217; H01L 21/02274; H01L 21/0254

(57) ABSTRACT

A semiconductor device includes a substrate: a first nitride semiconductor layer formed on the substrate; a second nitride semiconductor layer formed on the first nitride semiconductor layer and containing a gallium element; a source electrode and a drain electrode formed on the second nitride semiconductor layer and contacting the second nitride semiconductor layer; a third nitride semiconductor layer formed on the second nitride semiconductor layer and containing an indium element and an aluminum element; and a gate electrode formed on the third nitride semiconductor layer and formed between the source electrode and the drain electrode.

### CROSS-REFERENCE TO RELATED APPLICATION(S)

This application is based upon and claims the benefit of priority from the prior Japanese Patent Application No. 2017-249374, filed on Dec. 26, 2017, the entire contents of which are incorporated herein by reference.

### FIELD

Embodiments of the present invention relate to a semiconductor device.

### BACKGROUND

In a gallium nitride-based semiconductor device for large electric power used for communications, a radar, etc., a layer called an InAlN cap layer or an InAlGaN cap layer is formed on a GaN channel layer and an AlGaN barrier layer which are formed on a substrate of Si, SiC, or sapphire, thereby stabilizing a surface state and improving element characteristics, such as control of current collapse. However, when the InAlN cap layer or the InAlGaN cap layer exists, it is difficult to lower contact resistance at the time of formation of an ohmic electrode.

### BRIEF EXPLANATION OF THE DRAWINGS

FIG. 1 is a sectional view of a semiconductor device concerning a first embodiment.

FIG. 2A, FIG. 2B, FIG. 2C and FIG. 2D are diagrams showing a method for manufacturing the semiconductor device concerning the first embodiment.

FIG. 3 is a sectional view of a semiconductor device concerning a second embodiment.

FIG. 4A, FIG. 4B, FIG. 4C and FIG. 4D are diagrams showing a method for manufacturing the semiconductor device concerning the second embodiment.

FIG. 5 is a sectional view of a semiconductor device concerning a third embodiment.

FIG. 6A, FIG. 6B, FIG. 6C and FIG. 6D are diagrams showing a method for manufacturing the semiconductor device concerning the second embodiment.

### DETAILED DESCRIPTION

A semiconductor device according to an embodiment is provided with a substrate, a first nitride semiconductor layer which is formed on the substrate, a second nitride semiconductor layer which is formed on the first nitride semiconductor layer and contains a gallium element, a source electrode and a drain electrode which are formed on the second nitride semiconductor layer and are in contact with the second nitride semiconductor layer, a third nitride semiconductor layer which are formed on the second nitride semiconductor layer and contains an indium element and an aluminum element, and a gate electrode which is formed on the third nitride semiconductor layer and between the source electrode and the drain electrode.

### First Embodiment

Hereinafter, a semiconductor device concerning this embodiment will be explained with reference to the drawings.

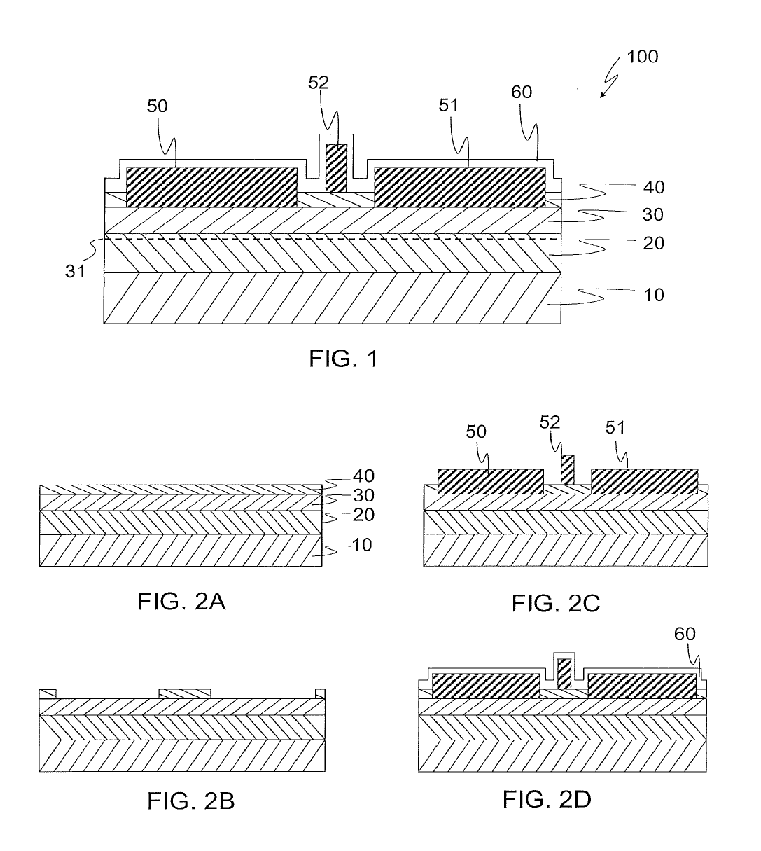

FIG. 1 is a sectional view of a semiconductor device 100 of the first embodiment.

A gallium nitride layer (a GaN layer, a first nitride semiconductor layer) 20 as a channel layer is formed on a substrate 10. A gallium-aluminum-nitride layer (an AlGaN layer, a second nitride semiconductor layer) 30 as a barrier layer is formed on the GaN layer 20. Furthermore, an indium nitride aluminum gallium layer (an InAlGaN layer, a third nitride semiconductor layer) 40 as a cap layer is formed on the AlGaN layer 30. The cap layer may be an InAlN layer. That is, the third nitride semiconductor layer 40 as the cap layer is a nitride semiconductor layer containing an indium element and an aluminum element.

On the AlGaN layer 30, a source electrode 50 and a drain electrode 51 are formed at a first gap. Moreover, the gate electrode 52 is formed between the source electrode 50 and the drain electrode 51 and on the InAlGaN layer 40. A second gap is formed between the gate electrode 52 and the source electrode 50, and a third gap is formed between the gate electrode 52 and the drain electrode 51. A side of the source electrode 50 is in contact with the InAlGaN layer 40, and a side of the drain electrode 51 is in contact with the InAlGaN layer 40.

Furthermore, on the InAlGaN layer 40, the source electrode 50, the drain electrode 51 and the gate electrode 52, a protective layer 60 is formed so that the whole of those may be covered.

Silicon (Si), silicon carbide (SiC), sapphire, gallium nitride (GaN), diamond, etc. are used for the substrate 10. However, in this embodiment, a material of the substrate 10 is not limited thereto.

The GaN layer 20, the AlGaN layer 30 and the InAlGaN layer 40 are nitride semiconductors. In this embodiment, these layers are III-V semiconductors in which a group III element, such as aluminum (Al), gallium (Ga) and indium (In), and a group V element of nitrogen (N) are combined.

Since, compared with Si, GaN has a large band gap and is excellent in high withstand voltage, GaN is used for a power device for large electric power which can be applied with the high voltage. Furthermore, since the saturation electronic speed of GaN is larger than that of Si, and the electron mobility of GaN is equivalent to that of Si, GaN is used also as a high frequency semiconductor device for microwave.

The GaN layer 20 (the first nitride semiconductor layer) and the AlGaN layer 30 (the second nitride semiconductor layer) are formed by combining materials of which inter-lattice distances are near.

The GaN layer 20 is different from the AlGaN layer 30 in the band gap. When the GaN layer 20 and the AlGaN layer 30 are bonded, a quantum well of energy level is formed near a bonded surface (a hetero interface), electrons are accumulated in the quantum well with high density, and a two-dimensional electron gas (2DEG) 31 is formed.

The InAlGaN layer 40 covers an upper end of the AlGaN layer 30, and terminates a dangling bond of a surface of the AlGaN layer 30. That is, the InAlGaN layer 40 prevents that a trap level is formed in the surface of the AlGaN layer 30, thereby preventing degradation of the characteristics of the semiconductor device 100.

The source electrode 50 and the drain electrode 51 are formed on the AlGaN layer 30, and each electrode 50 and 51 is in contact with the AlGaN layer 30 by ohmic contact. The gate electrode 52 is formed on the InAlGaN layer 40, and the gate electrode 52 is in contact with the InAlGaN layer 40 by Schottky contact. When forming the source electrode 50 and the drain electrode 51 which are ohmic electrodes, the InAlGaN layer 40 with a large band gap is etched, and the source electrode 50 and the drain electrode 51 are formed on the AlGaN layer 30, thereby enabling the formation of a good ohmic contact.

The protective layer 60 is formed of a nitride film etc. The nitride film includes silicon nitride (SiN), for example. The protective layer 60 has a role to protect each electrode from moisture etc. by covering each electrode.

A method for manufacturing the semiconductor device 100 of this embodiment will be explained using FIG. 2A to FIG. 2D. As for the semiconductor device 100, the crystal growth of GaN onto the substrate 10 is carried out by a metal organic chemical vapor deposition (MOCVD) method etc., and the GaN layer 20 is grown on the substrate 10. The MOCVD method is a method for epitaxially growing a semiconductor layer on the substrate 10, by supplying an organic metal and a carrier gas on the substrate 10 which is heated, and by producing the chemical reaction in a gaseous phase on the substrate 10.

After the GaN layer 20 is grown on the substrate 10, the AlGaN layer 30 is grown on the GaN layer 20 by supplying trimethyl aluminum (TMA) and trimethyl gallium (TMG) of organic metal materials and ammonia gas with carrier gas (nitrogen or hydrogen), and making them react.

After growing the AlGaN layer 30 on the GaN layer 20, the InAlGaN layer 40 is grown on the AlGaN layer 30 by supplying TMA, TMG, trimethyl indium (TMI), ammonia gas, and carrier gas, and by making them react similarly (FIG. 2A).

The MOCVD method is an example of the growth method of these nitride semiconductor layers, however, the growth method of the nitride semiconductor layer is not limited to the MOCVD method in this embodiment.

After growing up the InAlGaN layer 40, an etching treatment removes the grown InAlGaN layer 40 in part (FIG. 2B). An etching method is an inductively coupled plasma reactive ion etching (ICP-RIE), for example. The source electrode 50 and the drain electrode 51 are formed on the AlGaN layer 30 in a portion where the InAlGaN layer 40 is removed, and the gate electrode 52 is formed on the InAlGaN layer 40. The electrodes 50, 51 and 52 are formed by heat-treating metal layers prepared in order to make these electrodes (alloy treatment) (FIG. 2C).

Then, the protective layer 60 is deposited by a plasma-enhanced chemical vapor deposition (plasma-CVD) method etc. on the InAlGaN layer 40 and each electrode 50, 51 and 52 (FIG. 2D). The plasma CVD method is an example of the passivation method of the protective layer 60, however, the passivation method of the protective layer 60 is not limited to the plasma CVD method in this embodiment.

### Second Embodiment

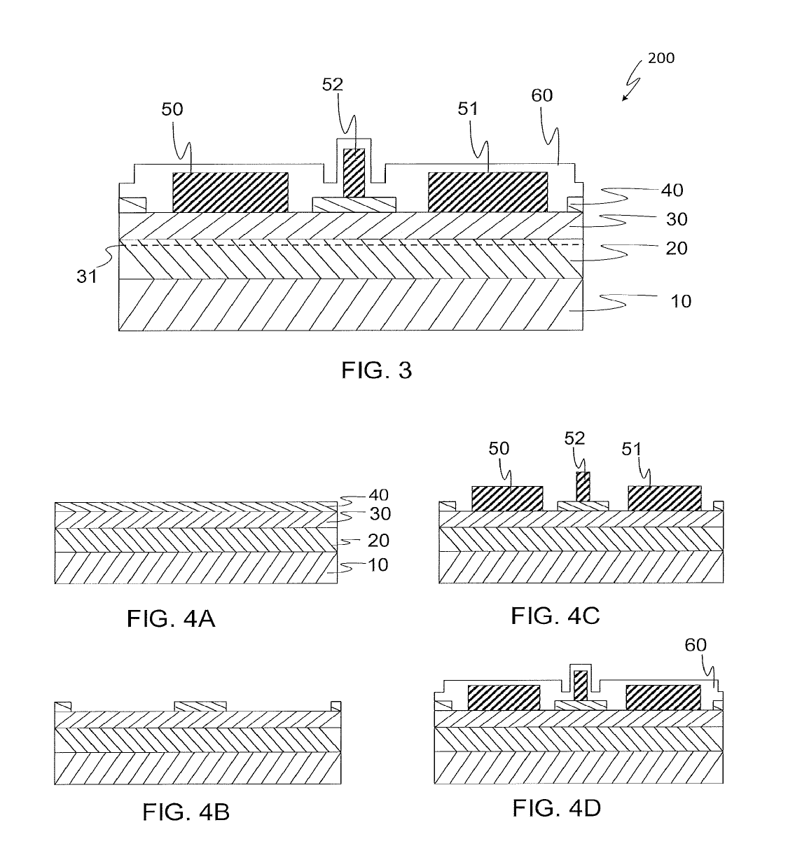

FIG. 3 is a diagram showing a semiconductor device 200 which is the second embodiment.

Although the side of each of the source electrode 50 and the drain electrode 51 is in contact with the InAlGaN layer 40 in the first embodiment, the source electrode 50 and the drain electrode 51 are not in contact with the InAlGaN layer 40 (those are in non-contact) in the second embodiment. That is, the source electrode 50 and the drain electrode 51 are arranged apart from the InAlGaN layer 40.

A manufacturing method of the second embodiment will be explained using FIG. 4A to FIG. 4D. First, the GaN layer 20, the AlGaN layer 30 and the InAlGaN layer 40 are grown on the substrate 10. Since a step of growing each layer (FIG. 4A) is the same as that of the first embodiment, an explanation is omitted.

Next, in order to form the source electrode 50 and the drain electrode 51, an etching treatment removes a part of the InAlGaN layer (FIG. 4B).

Then, the source electrode 50, the drain electrode 51 and the gate electrode 52 are formed. The source electrode 50 and the drain electrode 51 are formed on the AlGaN layer 30, and the gate electrode 52 is formed on the InAlGaN layer 40 (FIG. 4C). The source electrode 50 and the drain electrode 51 are formed so that they may not be in contact with the InAlGaN layer 40.

Finally, the protective layer 60 is deposited so that the protective layer 60 may cover the InAlGaN layer 40, the AlGaN layer 30, the source electrode 50, the drain electrode 51 and the gate electrode 52 (FIG. 4D). It should be noted that the method for etching and the method for depositing the protective layer 60 are the same as those of the first embodiment.

In the second embodiment, the source electrode 50 and the drain electrode 51 should just be formed in an area narrower than the etched portion of the InAlGaN layer 40, and the semiconductor device 200 of the second embodiment has a structure which is easier to manufacture as compared with the semiconductor device 100 of the first embodiment. Therefore, the second embodiment has the advantage that manufacturability is improved as compared with the first embodiment.

In FIG. 3 and FIG. 4A to FIG. 4D, the source electrode 50 and the drain electrode 51 are formed so that they may not be in contact with the InAlGaN layer 40. The semiconductor device of this embodiment is not limited to the semiconductor device in which those electrodes are not in contact with the InAlGaN layer 40 completely, but includes a semiconductor device in which a part of those electrodes is in contact with the InAlGaN layer 40. For example, in a semiconductor device of the second embodiment, at least a part of the side of the source electrode 50 or at least a part of the side of the drain electrode 51 may be in contact with the InAlGaN layer 40.

### Third Embodiment

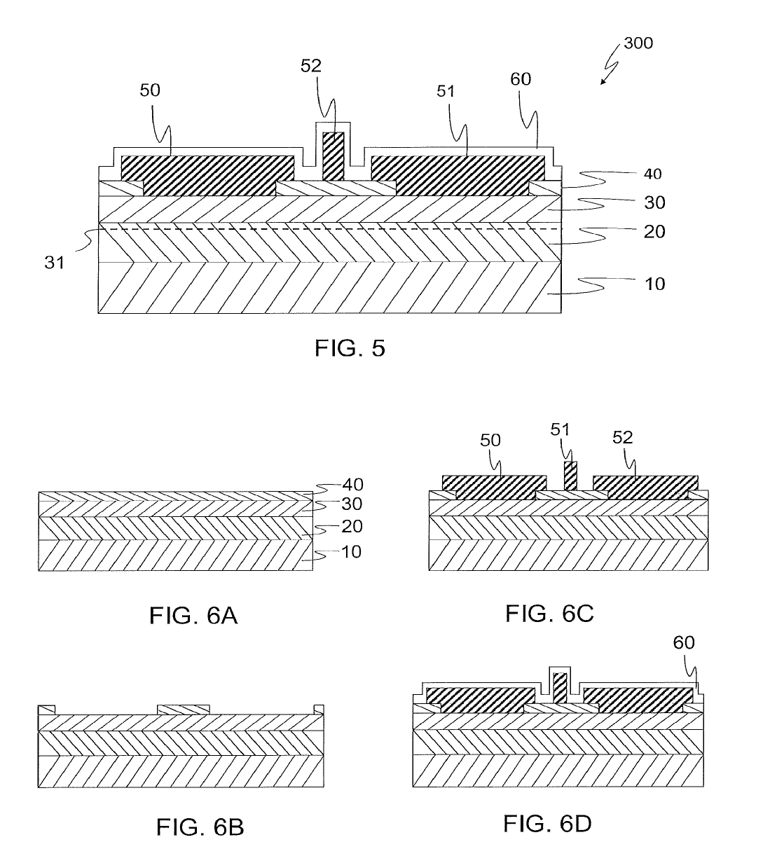

FIG. 5 is a diagram showing a semiconductor device 300 which is the third embodiment.

In the third embodiment, each of the source electrode 50 and the drain electrode 51 covers a part of the InAlGaN layer 40.

A manufacturing method of the third embodiment will be explained using FIG. 6A to FIG. 6D. First, the GaN layer 20, the AlGaN layer 30 and the InAlGaN layer 40 are grown on the substrate 10. Since a step of growing each layer (FIG. 6A) is the same as the first embodiment, an explanation is omitted.

Next, in order to form the source electrode 50 and the drain electrode 51, the InAlGaN layer 40 is removed, by an etching treatment, at only a portion in which the source electrode 50 and the drain electrode 51 are formed (FIG. 6B).

Then, the source electrode 50, the drain electrode 51 and the gate electrode 52 are formed. The source electrode 50 and the drain electrode 51 are formed on the AlGaN layer 30, and the gate electrode 52 is formed on the InAlGaN layer 40. At this time, the source electrode 50 and the drain electrode 51 are formed so as to cover a part of the InAlGaN layer 40 (FIG. 6C).

Finally, the protective layer 60 is deposited so as to cover the InAlGaN layer 40, the source electrode 50, the drain electrode 51 and the gate electrode 52 (FIG. 6D).

It should be noted that a method of the etching treatment and a method for depositing the protective layer 60 are the same as those of the first embodiment.

In the third embodiment, the source electrode 50 and the drain electrode 51 should just be formed in an area wider than the etched portion of the InAlGaN layer 40, the semiconductor device 200 of the third embodiment has a structure which is easier to manufacture as compared with the semiconductor device of the first embodiment like the second embodiment. Moreover, the source electrode 50 and the drain electrode 51 are formed in contact with the InAlGaN layer 40, thereby controlling occurrence of current collapse. Accordingly, the third embodiment can expect the performance equivalent to the first embodiment.

A shape of a tip (which is a portion covering the InAlGaN layer 40) of each of the source electrode 50 and the drain electrode 51 does not need to be the same as that of the tip shown in FIG. 5 and FIG. 6A to FIG. 6D.

Although some embodiments were described, the positions and shapes of the source electrode 50 and the drain electrode 51 against the InAlGaN layer 40 are not restricted to those of the embodiments, and the source electrode 50 and the drain electrode 51 may employ the different embodiments, respectively, for example, and one electrode may employ the combination of the different embodiments.

In addition, while certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What we claimed is:

1. A semiconductor device comprising:
a substrate;
a first nitride semiconductor layer formed on the substrate;
a second nitride semiconductor layer formed on the first nitride semiconductor layer and containing a gallium element;
a source electrode and a drain electrode formed on the second nitride semiconductor layer and being in contact with the second nitride semiconductor layer;
a third nitride semiconductor layer formed on the second nitride semiconductor layer and containing an indium element and an aluminum element; and
a gate electrode formed on the third nitride semiconductor layer and formed between the source electrode and the drain electrode.

2. The semiconductor device according to claim 1, wherein
a part of a side of the source electrode or a part of a side of the drain electrode is in contact with the third nitride semiconductor layer.

3. The semiconductor device according to claim 1, wherein
a side of the source electrode or a side of the drain electrode is in non-contact with the third nitride semiconductor layer.

4. The semiconductor device according to claim 1, wherein
a part of the source electrodes or a part of the drain electrodes covers at least a part of the third nitride semiconductor layer.

5. The semiconductor device according to claim 1, wherein
each of the source electrode and the drain electrode is in contact with the third nitride semiconductor layer.

6. The semiconductor device according to claim 1, wherein
each of a side of the source electrode and a side of the drain electrode is in contact with the third nitride semiconductor layer.

7. The semiconductor device according to claim 1, wherein
each of the source electrode and the drain electrode is not in contact with the third nitride semiconductor layer.

8. The semiconductor device according to claim 5, wherein each of a part of the source electrode and a part of the drain electrode covers at least a part of the third nitride semiconductor layer.

9. The semiconductor device according to claim 1, further comprising
a protective layer which covers the third nitride semiconductor layer, the source electrode, the drain electrode and the gate electrode.

10. The semiconductor device according to claim 1, wherein
the first nitride semiconductor layer is a channel layer, the second nitride semiconductor layer is a buffer layer and the third nitride semiconductor layer is a cap layer.
